(19) United States
(12) Patent Application Publication
(10) Pub. No.: US 2018/0275169 A1
(43) Pub. Date: Sep. 27, 2018

(54) Apparatus for Super-Fine Pitch Integrated Circuit Testing and Methods of Constructing

(71) Applicant: Marvell World Trade Ltd., St. Michael (BB)

(72) Inventor: Marc Jacobs, Redwood City, CA (US)

(73) Assignee: Marvell World Trade Ltd., St. Michael (BB)

(21) Appl. No.: 15/927,280

(22) Filed: Mar. 21, 2018

Related U.S. Application Data
(60) Provisional application No. 62/474,442, filed on Mar. 21, 2017.

(51) Int. Cl. G01R 1/073; G01R 31/28; G01R 3/00

(52) U.S. Cl. CPC G01R 1/07342; G01R 3/00; G01R 31/2889

(57) ABSTRACT

An apparatus, including methods of construction and use, for super-fine pitch integrated circuit testing is disclosed. The apparatus includes a substrate of one or more redistribution layers (RDLs), a plurality of vertical interconnect access (via) columns, a material that backs the substrate, and another material that protects the plurality of via columns. Semiconductor wafer fabrication processes are used to fabricate the apparatus, effective to enable the apparatus to test one or more IC die having pad pitch spacing of less than 50 um.

### CROSS REFERENCE TO RELATED APPLICATION

This present disclosure claims priority to U.S. Provisional Patent Application Ser. No. 62/474,442 filed Mar. 21, 2017 the disclosure of which is incorporated by reference herein in its entirety.

### BACKGROUND

Integrated circuit (IC) die, sometimes referred to as computer chips, are manufactured and tested in wafer form before being diced from the wafer and assembled in packages, modules, or as part of a printed circuit board. Wafer-level IC testing is a critical part of the IC die manufacturing process in which IC die that do not function properly can be identified and removed from the manufacturing flow. Feedback from wafer-level testing can be provided to product design engineers and manufacturing engineers to improve product design and reduce manufacturing costs. Wafer-level IC die testing can include burn-in/stress testing at high temperatures to screen IC die for reliability defects, functionality testing (basic functionality testing and speed testing), or parametric testing of structures on the IC die to monitor control of manufacturing processes.

Conventional wafer-level IC testing uses a probe card to provide electrical paths between instrumentation of a test system and test contact points of one or more IC die contained on a wafer. A probe card generally has electrical contacts, or probes, that are fabricated at a spacing that matches the spacing of the test contact points of the IC die. The probe card is typically fixed, using a probe card interface, to a wafer prober, which positions a wafer being tested relative to the probe card such that specific probes of the probe card make electrical contact with specific test contact points of the IC die contained on the wafer. Once electrical contact is made, signals can be exchanged, using the probe card, between the IC die being tested and testing instrumentation. Currently, probe cards manufacturing capabilities limit spacing of test contact points, at times imposing constraints on scaling IC die layouts and sizes.

Without a probe card capable of scaling to finer pitches, the quality assurance of an IC die, achieved through testing the IC die, and feedback necessary to make improvements to designs of the IC die are in jeopardy. Subsequently, performance of systems that the IC die may be integrated into, such as a computer, smart phone, or the like, can be impacted.

### SUMMARY

As semiconductor manufacturing processes improve, the features of the IC die shrink and the density of the test contact points increases. A probe card supporting super-fine pitches of less than 50 um is needed to test an IC die as the test contact points increase in density. Such a probe card will not only ensure testability of the IC die as the semiconductor manufacturing processes continue to improve, but also afford improvements in IC die layouts and sizes, allowing a minimizing surface area of the IC die to be consumed by test contact points, translating into IC die cost savings.

An apparatus, including methods of construction and use, for super-fine pitch integrated circuit testing is disclosed. The apparatus includes a substrate of one or more redistribution layers (RDLs), a plurality of vertical interconnect access (via) columns, a material that backs the substrate, and another material that protects the plurality of via columns. The method of construction includes fabricating the plurality of via columns into a carrier material, depositing the substrate of one or more RDLs on a surface of the carrier material, depositing a backing material on a surface of the substrate, revealing the plurality of via columns by removing the carrier material, and depositing a protective material around the plurality of via columns. The method of use includes aligning an integrated-circuit (IC) die to the apparatus, engaging the IC die to the apparatus, and testing the IC die such that signals are routed through the plurality of via columns and the substrate of the apparatus.

The details of one or more aspects are set forth in the accompanying drawings which are given by way of illustration only, and the description below. Other features, aspects, and advantages will become apparent from the description, the drawings, and the claims. Like reference numbers and designations in the various drawings indicate like elements.

### BRIEF DESCRIPTION OF THE DRAWINGS

The details of one or more aspects of an apparatus for super-fine pitch IC testing and methods of constructing are described below. The use of the same reference numbers in different instances in the description and the figures may indicate like elements.

FIG. 1 illustrates an example environment that includes a probe card testing an integrated circuit (IC) die.

FIG. 2 illustrates details of an example probe card configured for testing an IC die.

FIG. 3 illustrates an example method for fabricating a probe card in accordance with one or more embodiments.

FIG. 4 illustrates example cross sections of a probe card manufactured to include a substrate of redistribution layers (RDLs) and vertical interconnect access (via) columns.

FIG. 5 illustrates an example method for testing an IC die in accordance with one or more embodiments.

### DETAILED DESCRIPTION

It is desirable to test an integrated-circuit (IC) die prior to the IC die being encapsulated in a package for multiple reasons, including monitoring wafer fabrication process control, removing a faulty IC die from the manufacturing flow, or improving circuitry design. In some instances, the IC die may be tested in wafer form (prior to dicing the IC die from the wafer) while in others in may be tested post-dicing. Testing of the IC die first establishes a signal path between test instrumentation and test contact points contained on the IC die. The test contact points contained on the IC die may be test pads dedicated for testing, while in other instances the test contact points may be bonding pads that serve not only as an test contact point for testing, but also as a bonding point for wiring the die to the outside world as part of a packaging process. The test contact points on the IC die may also be microbumps, pillars, or the like.

Establishing a signal path between test instrumentation and test contact points of an IC die requires contacting, or probing, the test contact points with electrically conductive probes. Such probes are often arranged on a mechanism known as a probe card. As physical location of the test contact points typically varies with IC die designs, a custom routing of electrically conductive traces through a medium, or substrate, is needed to electrically connect test contact points of an IC die to test instrumentation.

Semiconductor manufacturing processes, using tools and techniques similar those used to fabricate an IC die, offer capabilities of matching geometries of the IC die. For example, processes used to manufacture advanced semiconductor packages may be utilized to manufacture probe cards capable of matching geometries of the IC die, including the sizes and pitches of features such as pads, microbumps, formed wires, or pillars. Through-via (vertical interconnect access) processes can be applied to manufacture electrically conductive probes while Redistribution Layer (RDL) processes can be applied to route electrically conductive traces through a substrate and perform a spacing transformation. This combination of manufacturing technologies replaces card-manufacturing technologies that simply do not have the capability to match geometries that are scaling to finer pitch and feature sizes.

The following discussion describes an operating environment and techniques that may be used to test an IC die using a super-fine pitch probe card. The discussion also includes describing manufacturing techniques that may be utilized to manufacture such a probe card. In the context of the present disclosure, reference is made to the operating environment by way of example only.

Operating Environment

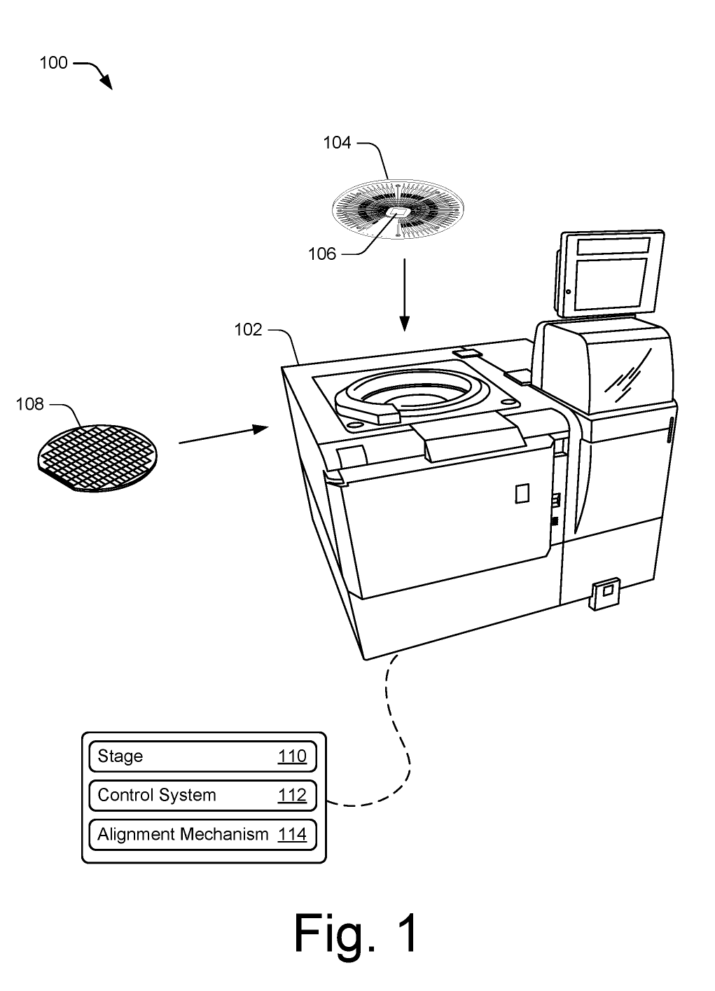

FIG. 1 illustrates an example operating environment 100 that includes an example wafer prober 102. The wafer prober 102 interfaces to test instrumentation (not illustrated) through a probe card interface 104. Included, as part of the probe card interface 104, is a probe card 106 having a substrate and a plurality of probes with tips.

In the operating environment 100, and as part of a process that tests one or more IC die, a semiconductor wafer 108 containing one or more IC die is positioned on a stage 110 of the wafer prober 102. Using a control system 112 and an alignment mechanism 114, the stage 110 positions the semiconductor wafer 108 relative to probe card 106, such that test contact points of an IC die contained on the semiconductor wafer 108 are aligned with the tips of probes of the probe card 106. In one example instance, the alignment may be an alignment during which an individual IC die is aligned to a single site probe card for single site testing. In another example instance, the alignment may be an alignment during which a plurality of IC die are aligned to a multiple site probe card for multiple site (parallel) testing.

In either example instance, the wafer prober 102 may use visual recognition, as part of the alignment mechanism 114, to compare test contact point locations of the IC die of the semiconductor wafer 108 and probe tip locations of the probe card 106 and perform a “best-fit” alignment algorithm. In addition to factors such as test contact point locations and probe tip locations, the best-fit algorithm may also take into account variables such as anticipated thermal expansion of the semiconductor wafer 108 (for at-temperature testing), location of an IC die to be tested relative to the center of the semiconductor wafer 108, the semiconductor wafer 108 thickness, nominal center of the probe card 106, or historical positioning errors of the stage 110. Statistical analysis of these variables can be reduced, by the control system 112, and used to determine positioning offsets to be used by the stage 110 prior to engaging the IC die with the probe card, effective to improve success rate of probes making electrical contact with the IC die.

After alignment, the stage 110 of the wafer prober 102 engages the IC die with the probe card 106 such that the tips of probes of the probe card 106 make electrical contact with test contact points of the IC die. Test signals are then communicated between the IC die and test instrumentation through the plurality of probes and the substrate of the probe card 106. The test signals may support a variety of IC die test types, including burn-in/stress testing, functionality testing, or parametric testing.

Although the operating environment 100 is described in the context of using automated test equipment (ATE), such as the wafer prober 102, probing and testing of the semiconductor wafer 108 may also be performed manually in a lab without the assistance of the wafer prober 102. In a lab, alternate “benchtop” techniques may be leveraged to achieve alignment and engagement of the semiconductor wafer 108 to the probe card 106. Also, as opposed to engaging a wafer, such as the semiconductor wafer 108 to the probe card, an individual IC die (diced from the semiconductor wafer 108) may be engaged and tested.

Techniques for Super-Fine Pitch Integrated Circuit Testing

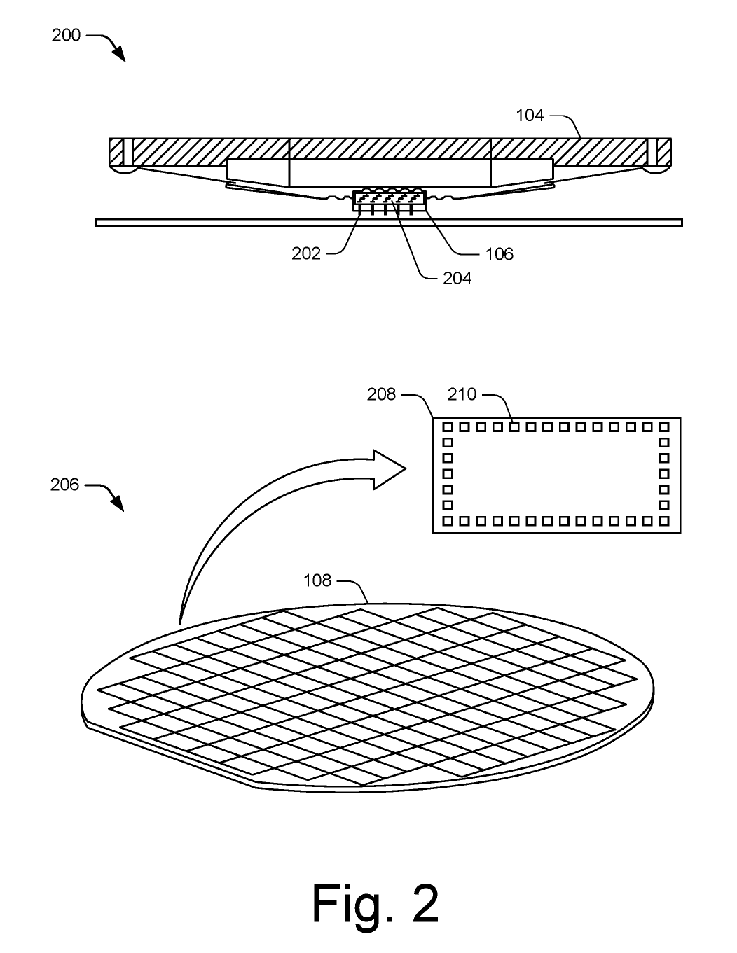

FIG. 2 illustrates details of an example probe card configured for testing an IC die. Illustration 200 depicts a cross section of the probe card interface 104 and the probe card 106 of FIG. 1. As illustrated, the probe card 106 includes a plurality of probes, such as probe 202, which can be used to make electrical contact with an IC die. The probe card 106 also includes a substrate 204, which includes a plurality of electrically conductive traces. The substrate serves as an intermediate electrical connection between the plurality of probe tips 202 and the probe card interface 104, performing a space transformation, or fan-out, of the plurality of electrically conductive traces. Test signals are communicated between the IC die and the probe card interface (connected to test instrumentation) through the plurality of probes 202 and the substrate 204 (e.g., the plurality of electrically conductive traces).

Illustration 206 depicts a semiconductor wafer 108 with a plurality of IC die, such as IC die 208. Each IC die 208 includes test contact points, such as test contact point 210, which can be used for testing the IC die. In some cases, the test contact point 210 may be a test pad that is dedicated for testing purposes, while in other cases the test contact point 210 may be a bond pad that serves not only as an electrical contact point for testing, but also as a bonding point for wiring the IC die 208 to the outside world as part of a packaging process. The test contact point 210 may also be a microbump, a pillar, or the like.

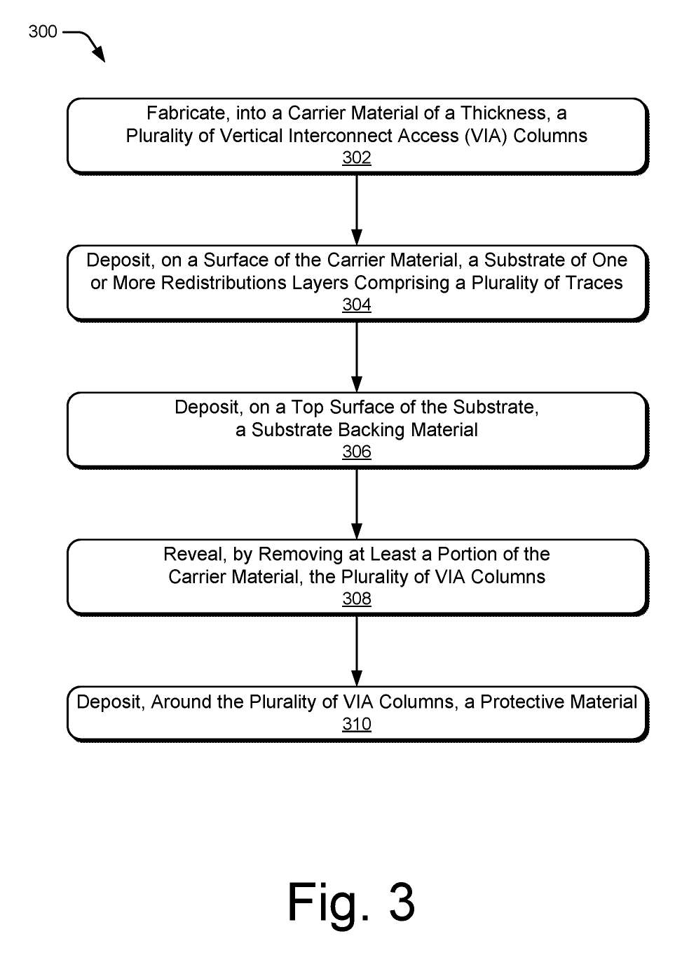

FIG. 3 illustrates an example method 300 for fabricating a probe card in accordance with one or more embodiments. The probe card can be, for example, the probe card 106 of FIG. 1.

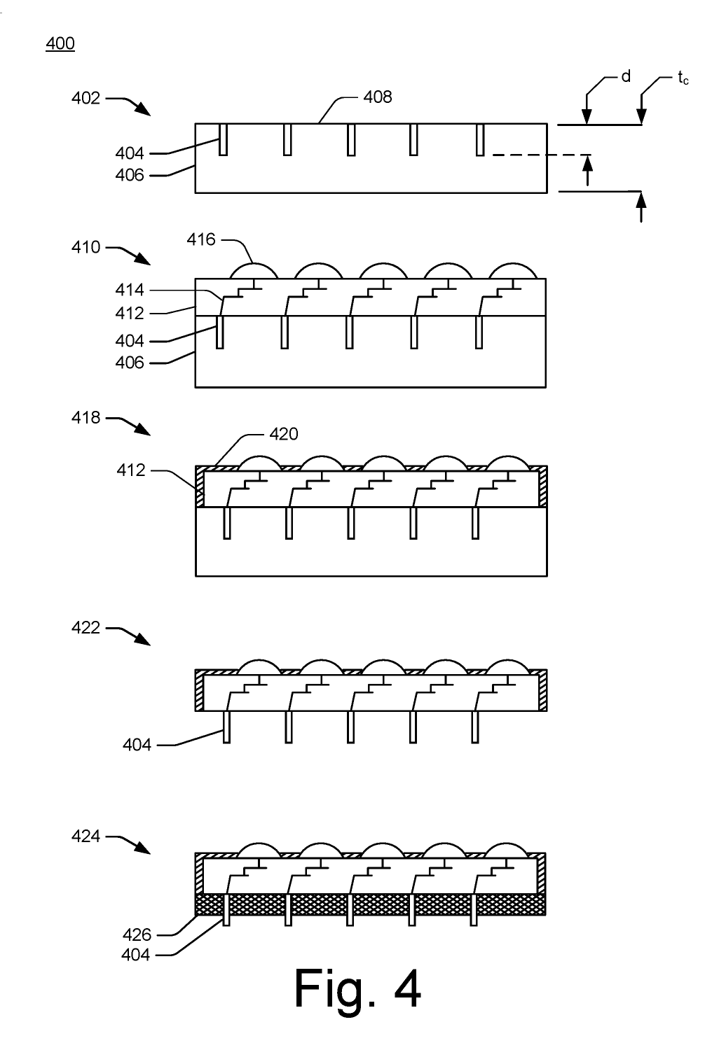

At 302, a plurality of vertical interconnect access (via) columns, sometimes referred to as plugs, are fabricated into a carrier material of a thickness. By way of example, consider FIG. 4, which illustrates example cross sections of a probe card manufactured to include a substrate of redistribution layers (RDLs) and vertical interconnect access (via) columns. At 402, a plurality of via columns, such as via column 404, are fabricated into a carrier material 406 of a thickness t_{c}. The carrier material may be a silicon-based material, a ceramic-based material, a glass-based material, a gallium arsenide material, or the like. The plurality of via columns 404 penetrates, orthogonally, from a surface 408 of the carrier material 406 a depth d that is less than the thickness t_{c} of the carrier material 406. The via columns 404 are made of an electrically conductive material, such as tungsten, copper, or the like, and are electrically isolated from one another. Processes used to fabricate the via columns can include processes used to manufacture through silicon via's (TSVs) as part of advanced semiconductor packaging processes, including photolithography (positive or negative photo-resist), etching (wet or dry), laser-drilling, or deposition (physical vapor deposition (PVD) or chemical vapor deposition (CVD)) processes.

Referring now back to FIG. 3, at 304 a substrate of one or more redistribution layers (RDLs) includes a plurality of traces, is deposited onto a surface of the carrier material. Continuing with the present example at 410, one or more RDLs 412 are deposited onto a surface of the carrier material 406, including a plurality of electrically conductive traces such as trace 414 (note that illustrations of the one or more RDLs and the plurality of traces have been simplified for clarity). The one or more RDL's 412 can be fabricated, for example, by subsequently layering traces made of a conductive material, such as copper, over a layer of a dielectric material, such as polyimide.

Each trace electrically connects a via column 404 with a respective interconnect 416 at a surface of the RDLs 412. As illustrated, the interconnect 416 is a solder ball that may be reflowed at elevated temperatures to connect the solder ball to corresponding pad of an external mechanism, such as the probe card interface 104 of FIG. 1. Alternatively, however, the interconnect 416 may be a pillar, a microbump, a formed wire, or a pad for a pogo-pin interface. In an instance where the interconnect 416 is not a solder ball capable of being reflowed, mechanical fixturing may be required.

Processes used to fabricate the one or more RDLs 412 can include combinations of processes used to manufacture IC die on a semiconductor wafer, including photolithography (positive or negative photo-resist), etching (wet or dry), laser-drilling, deposition (physical vapor deposition (PVD) or chemical vapor deposition (CVD)), sputtering, or plating processes. It is important to note that the one or more RDLs 412 serve, in effect, as a space transformation, relying on traces 414 to fan-out narrow pitches of via columns 404 to interconnects 416.

Referring again back to FIG. 3, at 306 a substrate-backing material is deposited on a top surface of the substrate. Continuing with the present example at 418, a substrate-backing material 420, such as an epoxy-resin based mold compound, is deposited on a top surface of the substrate. The substrate-backing material 420, dispensed in a liquid state, is deposited such that it surrounds perimeters of the interconnects 416 and maintains exposure of the interconnects 416 so that the interconnects 416 can be electrically connected to another mechanism (such as the probe card interface 104 of FIG. 1). Additional processes, such as etching around the perimeter of the substrate 412, may be performed such that the substrate-backing material 420 may also form on vertical edges of the substrate 412 as illustrated.

Referring again back to FIG. 3, at 308 the plurality of via columns is exposed by removing the carrier material. Continuing with 422 of the present example, the carrier material 406 has been removed to expose the plurality of via columns 404. The removal of the carrier material 406 may be accomplished, for example, by performing an isotropic etch without a photolithography or masking operation. Other techniques of removing the carrier material 406 may include a combination of photolithography and develop operations with dry etch or wet etch processes that are used as part of semiconductor manufacturing. Although 422 illustrates carrier material 406 being removed in its entirety, in some instances portions of carrier material 406 may remain. After the removal of the carrier material, the plurality of via columns 404 are, in effect, attached to a bottom surface of the substrate of one or more RDLs 412.

Referring again to FIG. 3, at 310 a protective material is filled around the plurality of via columns. As illustrated at 424, a protective material 426 such as polyimide (PI), polybenzoxazole (PBO), epoxy-resin based mold compound, or the like, can be used to protect the bases of the via columns 404 and provide stress relief. The protective material 426 can be applied using a liquid dispense process, such as a spinning process. After application of the protective material 426, tips of the via columns 404 remain exposed so that they might be used to make electrical contact with a test contact point of an IC die, such as the test contact point 210 of FIG. 2. Additional processes, such as plating, may be performed on the tips of the via columns 404 in order to enhance tip electrical conductivity or connectivity properties.

Method 300 recites operations necessary to manufacture the probe card 106 of FIG. 1. After completing method 300, the probe card 106 may be diced from the material stack (e.g., the RDLs 412, the substrate-backing material 420, and the protective material 426) and integrated with a probe card interface, such as the probe card interface 104 of FIG. 1. In the event the interconnects 416 are solder balls, a reflow process may be used to integrate the probe card 106 with the probe card interface 104. In the event the interconnects 416 are test contact points, mechanical fixturing may be required to integrate the probe card 106 with the probe card interface 104.

Enhancements to the probe card interface 104 may be performed to enhance functionality of the probe card 106 within the operating environment 100, including the addition of mechanical compliance mechanisms (sheets of compliant material, springs, or the like). Such enhancements may be implemented to improve co-planarity between tips of via columns 404 and test contact points of the semiconductor wafer 108 during engagement.

The probe card 106, fabricated according to the method 300, is fabricated to have via columns 404 that are less than 50 um in length and tips that are less than 10 um in diameter, allowing the probe card 106 to be used for super-fine pitch integrated circuit testing. The combination of semiconductor manufacturing technologies by method 300 replaces card-manufacturing technologies that do not have the capability to achieve such dimensions. With such dimensions, the via columns 404 may be used for high frequency testing, make electrical contact with small test contact points, and provide operating margin to other systems, such as positioning mechanisms of the stage 110 of the wafer prober 102. The geometries of the via columns 404 further accommodate via column spacing on pitches of less than 50 um, allowing electrical contact with test contact points spaced on pitches of less than 50 um.

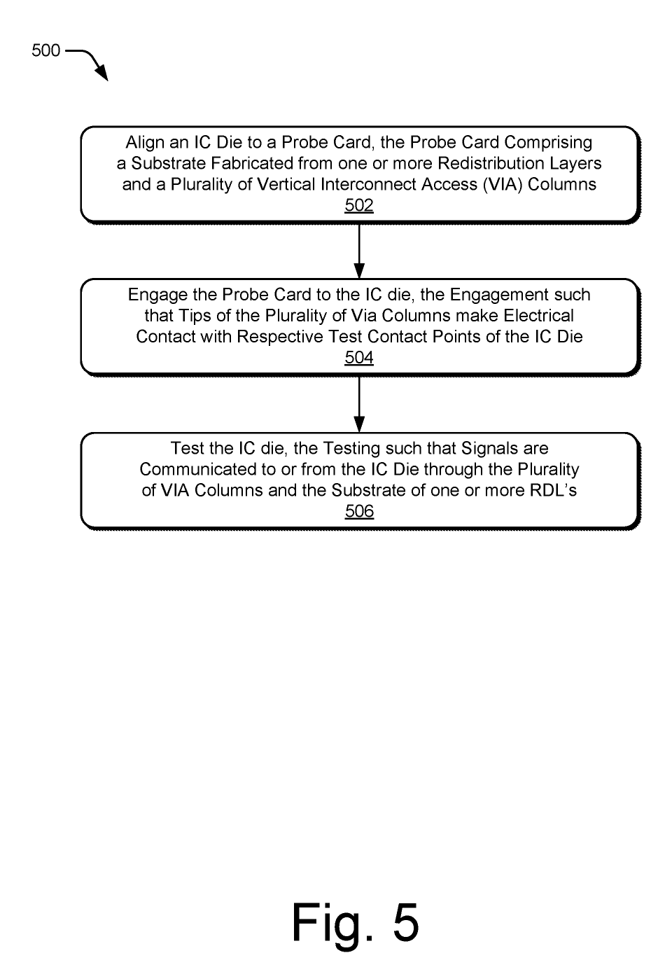

FIG. 5 illustrates an example method 500 for testing an IC die in accordance with one or more embodiments. Testing the IC die may, for example, be performed in an operating environment such as the operating environment 100 of FIG. 1. Alternatively, testing of the IC die may be performed in a benchtop environment, not using the wafer prober 102 of FIG. 1 and, instead, relying on other manual or automated positioning/engagement mechanisms.

At 502, an integrated circuit (IC) die is aligned to a probe card. The probe card includes a substrate of one or more redistribution layers (RDLs) and a plurality of vertical interconnect access (via) columns. Bases of the plurality of via columns may be surrounded by a protective material. The IC die may be the IC die 208 of FIG. 2. The probe card may be the probe card 106 of FIG. 1, where the one or more RDL's are the RDL's 412 of FIG. 4 and the plurality of via columns are the via columns 404 of FIG. 4.

The one or more RDL's can be fabricated, for example, by subsequently layering traces made of a conductive material, such as copper, over layers of a dielectric material, such as polyimide.

In some instances, the plurality of via columns may be, for example, a tungsten material that provides excellent wear characteristics and has the ability to penetrate layers of oxide that may have formed on a test pad. In other instances, the plurality of columns may be a copper material with excellent electrical conduction properties.

The protective material may be, for example, a polyimide (PI) material, a polybenzoxazole (PBO) material, or an epoxy-resin based mold compound material that, when filled around the bases of the plurality of via columns, provides stress relief to the plurality of via columns, thereby preventing their breakage or damage. The protective material may also serve as an electrical shield, minimizing “cross-talk” amongst the plurality of via columns during testing of the IC die.

At 504, the probe card is engaged to the IC die, the engagement such that tips of the plurality of via columns make electrical contact with respective test contact points of the IC die. The probe card may be probe card 106, the IC die may be IC die 208, and the via columns may be via columns 404. The test contact points of the IC die may be test contact points 210 of FIG. 2.

At 506, the IC die is tested. The IC die is tested such that test signals are communicated to and from the IC die through the plurality of via columns and the substrate of one or more RDLs of the probe card. The IC die may be IC die 208, the via columns may be via columns 404, the one or more RDLs may be RDLs 412.

What is claimed is:

1. A method for testing an integrated circuit (IC) die, the method comprising:
aligning an IC die to a probe card, the probe card comprising:
a substrate, the substrate fabricated from one or more redistribution layers (RDLs) and having a plurality of interconnect points at a top surface of the substrate;
a plurality of vertical interconnect access (via) columns, each via column attached at a bottom surface of the substrate and electrically connected to a respective interconnect point at the top surface through an electrically conductive trace routed through the substrate;
a substrate-backing material on the top surface of the substrate, the substrate-backing material surrounding perimeters of each interconnect point and exposing each interconnect point; and
a protective material surrounding the plurality of via columns, the protective material filled such that bases of the plurality of via columns are protected by the protective material and that tips of the plurality of via columns remain exposed;
engaging the IC die to the probe card, the engaging such that the tips of the plurality of via columns make electrical contact with respective test contact points of the IC die; and
testing the IC die, the testing such that signals are communicated to or from the IC die through the plurality of via columns and the substrate of the probe card.

2. The method of claim 1, wherein aligning the IC die to the probe card is performed by a wafer prober using visual recognition and performing a best-fit alignment algorithm.

3. The method of claim 1, wherein engaging the IC die to the probe card is performed by a stage of a wafer probe.

4. The method of claim 1, wherein testing the IC die includes burn-in/stress testing, functionality testing, or parametric testing.

5. The method of claim 1, wherein the method is performed manually in a lab environment.

6. A method for fabricating an electrically conductive apparatus, the method comprising:
fabricating, into a carrier material of a thickness, a plurality of vertical interconnect access (via) columns, where each via column:
penetrates, orthogonally, from a surface of the carrier material into the carrier material a depth that is less than the thickness of the carrier material;
is electrically isolated; and
is electrically conductive;
depositing, on the top surface of the carrier material, a substrate of one or more redistribution layers (RDLs), the RDLs comprising a plurality of electrically conductive traces, each trace routed from a bottom surface of the substrate to a top surface of the substrate, each trace electrically connected to a respective interconnect at a top surface of the substrate;
depositing, on a top surface of the substrate, a substrate-backing material, the substrate-backing material surrounding perimeters of each interconnect point and exposing each interconnect point;
revealing, by removing at least a portion of the carrier material, the plurality of via columns; and
filling, around the plurality of via columns, a protective material, the protective material filled such that bases of the via columns are protected by the protective material and that tips of the via columns remain exposed.

7. The method of claim 6, wherein fabricating the plurality of via columns relies on a dry etch, a wet etch, or a laser-drilling process.

8. The method of claim 6, wherein fabricating the plurality of via columns relies on a chemical vapor deposition (CVD) or physical vapor deposition (PVD) process.

9. The method of claim 6, wherein depositing the substrate of one or more RDLs relies on a sputtering or a plating process.

10. The method of claim 6, wherein depositing the substrate-backing material on the top surface relies on a liquid dispensing process.

11. The method of claim 6, wherein revealing the plurality of via columns relies on an isotropic etching process.

12. The method of claim 6, wherein revealing the plurality of via columns relies on a combination of at least one photolithography and develop operation with a dry etch or wet etch processes.

13. The method of claim 6, wherein in filling the protective material relies on a liquid dispense process.

14. A probe card comprising:
a substrate, the substrate fabricated from one or more redistribution layers (RDLs) and having a plurality of interconnect points at a top surface of the substrate;
a plurality of vertical interconnect access (via) columns, each via column attached at a bottom surface of the substrate and electrically connected to a respective interconnect point at the top surface through an electrically conductive trace routed through the substrate;
a substrate-backing material on the top surface of the substrate, the substrate-backing material surrounding perimeters of each interconnect point and exposing each interconnect point; and
a protective material surrounding the plurality of via columns, the protective material filled such that bases of the via columns are protected by the protective material and that tips of the via columns remain exposed.

15. The probe card of claim 14, wherein the interconnect points at the top surface of the substrate are solder balls, pillars, microbumps, formed wires, or pads.

16. The probe card of claim 14, wherein the plurality of vertical interconnect access (via) columns are tungsten or copper.

17. The probe card of claim 14, wherein the substrate-backing material is an epoxy-resin based mold compound.

18. The probe card of claim 14, wherein the protective material is a polyimide (PI) material, a polybenzoxazole (PBO) material, or an epoxy-resin based mold compound.

19. The probe card of claim 14, wherein the via are columns spaced on pitches less than 50 um.

20. The probe card of claim 14, wherein the via columns are less than 50 um in length.
